(19) United States
(12) Patent Application Publication
(10) Pub. No.: US 2002/0185067 A1
(43) Pub. Date: Dec. 12, 2002

(54) Apparatus and method for in-situ cleaning of a throttle valve in a CVD system

(75) Inventor: Allan Upham, Wappingers Falls, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY

(21) Appl. No.: 09/876,587

(22) Filed: Jun. 7, 2001

(51) Int. Cl. B08B 5/02; C23C 16/00

(52) U.S. Cl. 118/715; 134/22.18; 134/1.1; 118/723 IR; 156/345.35; 156/345.29

(57) ABSTRACT

The present invention relates generally to the field of semiconductor device manufacturing, and more specifically to an apparatus and method for in-situ cleaning of a throttle valve in a chemical vapor deposition (CVD) system. In the exhaust flow control apparatus of the CVD system, which comprises a chamber isolation valve, throttle valve and vacuum pump, means are provided for introducing cleaning gases downstream of the chamber isolation valve and upstream of the throttle valve. Such means may include a cleaning isolation valve connected to a cleaning gas source. Means for generating a reactive plasma of the cleaning gases, just before the throttle valve, may also be provided. During cleaning of the throttle valve, the CVD chamber is isolated, by closing the chamber isolation valve, and cleaning gases are flowed into the throttle valve, by opening the cleaning isolation valve.

### FIELD OF THE INVENTION

The present invention relates generally to the field of chemical vapor deposition (CVD) in semiconductor device manufacturing, and more specifically to a method for in-situ cleaning of a throttle valve in a CVD system.

### BACKGROUND OF THE INVENTION

Chemical vapor deposition (CVD) processes are used widely in the manufacture of semiconductor devices. Generally, CVD involves exposing a semiconductor wafer to a reactive gas under carefully controlled conditions including elevated temperatures, sub-ambient pressures and uniform reactant gas flow rate, resulting in the deposition of a thin, uniform layer or film on the surface of the substrate. The undesired gaseous byproducts of the reaction are then pumped out of the deposition chamber. The CVD reaction may be driven thermally or by a reactant plasma, or by a combination of heat and plasma. A typical CVD system is a single-wafer system utilizing a high-throughput CVD chamber.

A typical CVD process begins with heating of the CVD chamber to a temperature between about 250° C. and about 1,000° C. A semiconductor substrate is placed in the chamber on a receptor, typically known as a susceptor, which is generally made of ceramic or anodized aluminum. Next, reactant gases are introduced into the chamber, while regulating the chamber pressure. The chamber pressure may be controlled to as low as 1 torr up to as high as atmospheric pressure. The gases react in the chamber to form a deposition layer on the surface of the wafer.

Chamber pressure is precisely controlled by an inlet flow regulating device which regulates the flow rates of the gases into the chamber, and by an exhaust flow control apparatus attached to the exhaust gas port of the chamber. The exhaust flow control apparatus typically consists of an isolation valve, a throttle valve and a vacuum pump. The isolation valve is typically connected directly to the exhaust gas port of the reaction chamber, and the throttle valve is typically installed downstream from the isolation valve at a distance of approximately 6-10 inches away from the reaction chamber exhaust port. The vacuum pump is installed downstream from both the isolation valve and the throttle valve. During a typical deposition process, the isolation valve remains open while the throttle valve cycles between the open and closed positions to regulate the gas pressure in the chamber. The position of the throttle valve is controlled by a servo-motor which is in turn controlled by a closed-loop control system based on feed-back signals from a pressure manometer mounted in the reaction chamber.

In a typical deposition process, reactant gases enter the reaction chamber and produce films of various materials on the surface of a substrate for various purposes, such as for dielectric layers, insulation layers, etc. The various materials deposited include epitaxial silicon, polysilicon, silicon nitride, silicon oxide, and refractory metals such as titanium, tungsten and their silicides. Most of the material produced from the reactant gases is deposited on the wafer surface. However, some material also is inevitably deposited on other surfaces inside the chamber, and some material also may be deposited on the throttle valve. Deposition of unwanted film on the throttle valve is more likely during deposition of certain materials, such as silicon oxide, which require a relatively high chamber pressure. As unwanted material is deposited on the throttle valve, the precise operation of the throttle valve is diminished, thereby compromising the precise control of the reactant gas pressure inside the reaction chamber.

In a typical CVD system, after each deposition process wherein a film is deposited onto a semiconductor substrate and the substrate is removed from the chamber, a cleaning gas or mixture of cleaning gases is purged through the reaction chamber in order to clean unwanted deposits from the chamber interior surfaces, including the chamber walls and the susceptor. A typical cleaning gas system is a mixture of nitrogen trifluoride, hexafluoroethane and oxygen for cleaning unwanted silicon oxide films from the chamber interior. A plasma gas is typically ignited in the chamber to enhance the efficiency of the cleaning gas mixture. However, the reactive species of the cleaning gas cannot reach the throttle valve for effective cleaning due to the limited lifetime of the reactive species. Consequently, after multiple deposition and cleaning processes are performed in the chamber, a substantial amount of unwanted silicon oxide film is deposited and remains on the throttle valve, rendering it nonfunctional. That is, a sufficient amount of material is deposited on the interior surfaces of the throttle valve to prevent smooth motion of the throttle valve and accurate pressure control in the reaction chamber. This poor pressure control in the reaction chamber contributes to the production of semiconductor devices having insufficient reliability.

In addition, deposited material which builds up on the throttle valve may become dislodged and travel back through the isolation valve and exhaust gas port, and into the reaction chamber. Semiconductor wafers subsequently processed in the CVD chamber will be exposed to this foreign material, which will negatively impact manufacturing yield.

This problem of deposited material build-up on the throttle valve requires complete disassembly of the throttle valve assembly and manual cleaning by a wet chemistry technique. This is a very labor intensive and time consuming process which leads to poor throughput and increased cost of manufacturing. Moreover, after each manual disassembly and cleaning, the entire exhaust flow control system must be recalibrated in order to resume processing of semiconductor wafers in the reaction chamber.

Furthermore, if the reaction chamber has become contaminated with foreign material which has been dislodged from the throttle valve, the entire chamber must be opened and cleaned manually through a similarly labor intensive process. Once the chamber cleaning has been completed, the entire CVD system must be recalibrated and requalified in order to resume processing of semiconductor wafers in the reaction chamber.

An in-situ cleaning method and apparatus has been proposed by Robles et al. in U.S. Pat. No. 5,707,451. Robles et al. reposition the throttle valve assembly so that it is located upstream of the isolation valve and therefore closer to the exhaust gas port of the reaction chamber. Locating the throttle valve adjacent to the chamber increases the chance that some of the reactive species of the chamber cleaning gas may reach the throttle valve within their limited lifetime. However, this arrangement still suffers from reduced cleaning efficiency with regard to the throttle valve, because the throttle valve still is located relatively far from the plasma gas which is ignited in the chamber. Thus, most of the reactive species of the cleaning gas still do not reach the throttle valve for effective cleaning due their limited lifetime. More importantly, due to the absence of an isolation valve between the throttle valve and the reaction chamber, it is impossible in this arrangement to prevent material dislodged from the throttle valve, or any other foreign material in the CVD exhaust system, from contaminating the chamber.

### SUMMARY OF THE INVENTION

The present invention eliminates the aforementioned problems by providing an in-situ apparatus and method for effectively cleaning a throttle valve in a CVD system.

In one aspect of the present invention, an exhaust flow control apparatus attached to a CVD chamber, for controlling an exhaust flow passage and for regulating gas pressure in said CVD chamber, is disclosed. The exhaust flow control apparatus comprises: an isolation valve in fluid communication with said CVD chamber, for opening and closing said exhaust flow passage; a throttle valve mounted downstream from and in fluid communication with said isolation valve, for regulating gas pressure in said CVD chamber; means for introducing a cleaning gas into said exhaust flow passage downstream of said isolation valve and upstream of said throttle valve; and a vacuum pump mounted downstream from and in fluid communication with said throttle valve, for evacuating gas from said CVD chamber. The apparatus optionally may further comprise means for applying RF power in said exhaust flow passage downstream of said isolation valve and upstream of said throttle valve, for generating a reactive plasma of said cleaning gas.

In another aspect of the present invention, an exhaust flow control apparatus attached to a CVD chamber, for controlling an exhaust flow passage and a cleaning gas flow passage, and for regulating gas pressure in said CVD chamber, is disclosed. The exhaust flow control apparatus comprises: a first isolation valve in fluid communication with said CVD chamber, for opening and closing said exhaust flow passage; a second isolation valve in fluid communication with a cleaning gas source, for opening and closing said cleaning gas flow passage; a throttle valve mounted downstream from and in fluid communication with said first isolation valve and said second isolation valve, for regulating gas pressure in said CVD chamber; and a vacuum pump mounted downstream from and in fluid communication with said throttle valve, for evacuating gas from said CVD chamber. The apparatus optionally may further comprise an RF power source for generating a reactive plasma of said cleaning gas in said exhaust flow passage downstream of said isolation valve and upstream of said throttle valve.

In yet another aspect of the present invention, a method for cleaning a throttle valve attached to a CVD chamber is disclosed. The method comprises the steps of: isolating said throttle valve from said CVD chamber; and flowing at least one cleaning gas into said throttle valve at a temperature and pressure and for a length of time such that unwanted film deposits are removed from said throttle valve. The method optionally may further comprise the step of generating a reactive plasma of said cleaning gas, prior to the step of flowing said cleaning gas into said throttle valve.

### BRIEF DESCRIPTION OF THE DRAWINGS

The features of the invention believed to be novel and the elements characteristic of the invention are set forth with particularity in the appended claims. The drawings are for illustration purposes only and are not drawn to scale. Furthermore, like numbers represent like features in the drawings. The invention itself, however, both as to organization and method of operation, may best be understood by reference to the detailed description which follows, taken in conjunction with the accompanying drawings, in which:

FIG. 1A is a schematic view of a prior art exhaust flow control apparatus;

FIG. 1B is a schematic view of an exhaust flow control apparatus of the present invention; and

FIG. 2 is a process flow diagram for a CVD chamber and exhaust flow control apparatus of the present invention.

### DETAILED DESCRIPTION OF THE PREFERRED EMBODIMENTS

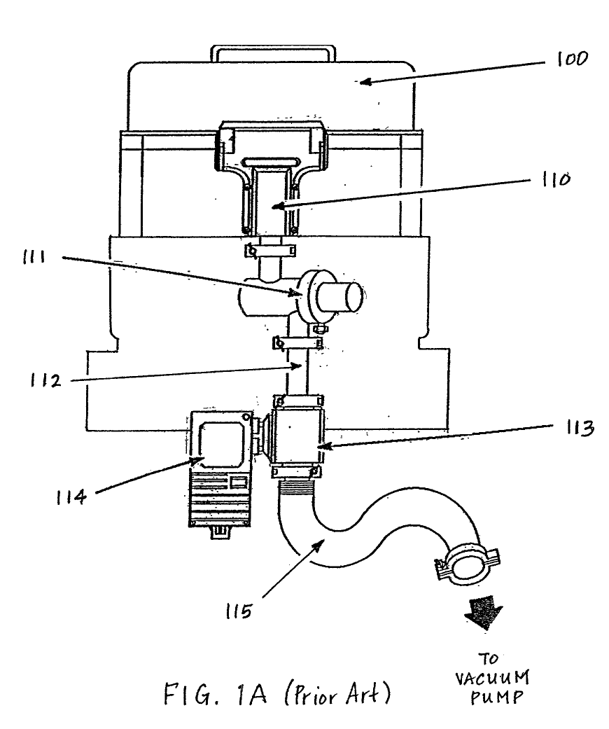

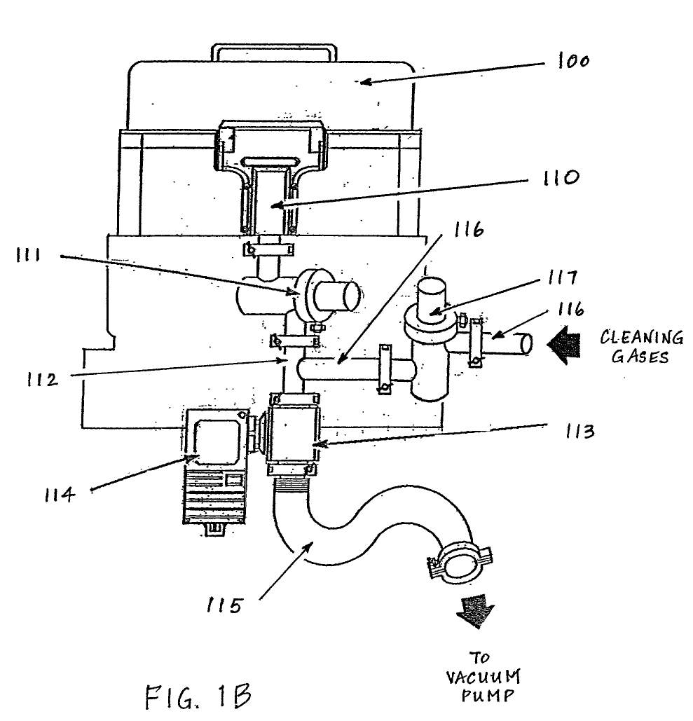

FIG. 1A shows a typical prior art exhaust flow control apparatus attached to a CVD system, such as the Precision 5000 System available from Applied Materials, Inc., Santa Clara, Calif. A CVD reaction chamber 100 for processing semiconductor wafers has an exhaust flow control apparatus attached to the side of the chamber through a flow adapter 110. Connected to the flow adapter 110 is a chamber isolation valve 111 for the opening and closing of the flow passage therein. Throttle valve 113 is connected to and in fluid communication with the chamber isolation valve 111 via exhaust pipe 112. Throttle valve 113 is controlled by a precision servo-motor 114 which is in turn controlled by closed-loop feedback signals received from a pressure manometer (not shown) attached to the CVD chamber 100. The gases exhausted from the CVD chamber 100 pass through flow adapter 110, chamber isolation valve 111, exhaust pipe 112 and throttle valve 113 into flow passage pipe 115 to a vacuum pump (not shown).

In this prior art arrangement of the exhaust flow control apparatus, cleaning gases used in CVD chamber 100 for removing unwanted deposits from surfaces of the chamber interior must travel through flow adapter 110, chamber isolation valve 111 and exhaust pipe 112 before reaching throttle valve 113. A plasma gas typically is ignited in CVD chamber 100 to enhance the efficiency of the cleaning gas mixture. However, the reactive species of the cleaning gas cannot reach throttle valve 113 for effective cleaning due the limited lifetime of the reactive species. Consequently, after multiple deposition and cleaning processes are performed in chamber 100, a substantial amount of unwanted film is deposited and remains on throttle valve 113, rendering it nonfunctional. That is, a sufficient amount of material is deposited on the interior surfaces of throttle valve 113 to prevent smooth motion of the throttle valve and accurate pressure control in reaction chamber 100.

FIG. 1B shows an improved exhaust flow control apparatus according to the present invention. In this embodiment, means are provided for introducing a cleaning gas downstream of chamber isolation valve 111 and upstream of throttle valve 113, by connecting a cleaning gas pipe 116 via a T-connection to exhaust pipe 112, thereby forming a cleaning gas flow passage. A cleaning isolation valve 117 is installed in cleaning gas pipe 116, for opening and closing the cleaning gas flow passage.

While gases are exhausted from CVD chamber 100, chamber isolation valve 111 remains open, and cleaning isolation valve 117 remains closed. Throttle valve 113 cycles between the open and closed positions as in a conventional CVD system in order to regulate the chamber pressure. Throttle valve 113 is controlled by servo-motor 114 which is in turn controlled by closed loop feedback signals received from a pressure manometer (not shown) attached to the CVD chamber 100.

When cleaning of throttle valve 113 is desired, chamber isolation valve 111 is closed, and cleaning isolation valve 117 is opened. Cleaning gases are introduced into cleaning gas pipe 116, pass through cleaning isolation valve 117, and enter throttle valve 113. A plasma gas may be ignited by an RF power source (not shown) just before throttle valve 113, for example in cleaning gas pipe 116 or in exhaust pipe 112. Alternatively, a plasma gas may be ignited just before cleaning isolation valve 117, so long as the distance to be traveled through cleaning isolation valve 117, cleaning gas pipe 116 and exhaust pipe 112 is not excessive. Cleaning gases and byproducts then continue through flow passage pipe 115 to a vacuum pump (not shown).

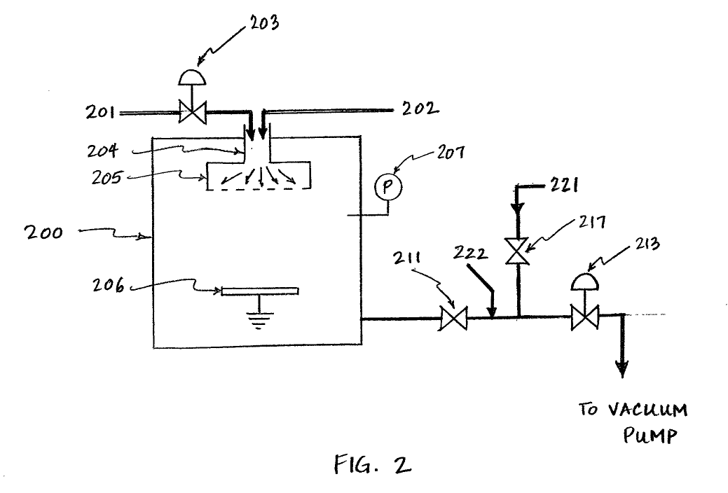

FIG. 2 shows a process flow diagram for a CVD process in which a CVD chamber 200 is used. Reactant gases 201 flow into chamber 200 through flow control valve 203, gas inlet 204, and gas distribution plate 205. Gas inlet 204 and gas distribution plate 205 also act as the upper electrode for the RF source. Gas distribution plate 205 is sometimes called a showerhead. The lower electrode or susceptor 206 is normally grounded when RF power is required. A RF generator (not shown) may provide RF power 202 through a matching network (not shown) to the upper electrode (gas inlet 204 and gas distribution plate 205). A pressure manometer 207 monitors the gas pressure in chamber 200.

There are a number of different types of thin films that can be deposited using CVD. The reactant gases to be used, and the chamber pressure and temperature, vary depending on the type of thin film desired. For silicon oxide films, the reactant gases may include tetraethoxyorthosilicate (TEOS), optionally with a carrier gas such as helium, oxygen (O₂), and ozone (O₃), or silane (SiH₄) and nitrous oxide (N₂O). The chamber pressure may be maintained at between about 40 torr and about 600 torr during the deposition of silicon oxide films, or may be maintained as low as about 8 torr for plasma-enhanced CVD. The temperature of the chamber is elevated to usually greater than 100° C. At this elevated temperature, and if desired, with RF applied, the gases will react and deposit a silicon oxide layer on the surface of the wafer.

During the deposition process, chamber isolation valve 211 remains open and cleaning isolation valve 217 remains closed. Gases from the reaction chamber 200 are exhausted through chamber isolation valve 211 and throttle valve 213, to a vacuum pump (not shown). Throttle valve 213 cycles between the open and closed positions to regulate the gas pressure in chamber 200. The position of throttle valve 213 is controlled by a servo-motor (not shown) which is in turn controlled by a closed-loop control system based on feed-back signals from pressure manometer 207.

Reactant gases deposit a film not only on the semiconductor wafer, but also on all of the interior surfaces of chamber 200, as well as on throttle valve 213. When the deposition process is completed, the wafer is removed from the chamber and a cleaning process is performed to remove deposits from the walls of the chamber. For the chamber clean, cleaning gases 201 are flowed into the chamber 200 through gas inlet 204 and gas distribution plate 205.

For cleaning following a silicon oxide film deposition, nitrogen trifluoride (NF₃), hexafluoroethane (C₂F₆) and oxygen (O₂) may be used. The flow rate of the cleaning gases is controlled such that the chamber pressure can be maintained at usually less than 200 torr. The temperature inside chamber 200 is maintained between about 100° C. to about 500° C. A plasma is ignited in the cleaning gas by applying RF power 202, thereby causing the gas to react with the deposit layers and etch the layers away. RF power of about 700 watts to about 1500 watts, usually about 900 watts, may be applied.

During the chamber cleaning process, cleaning gases are exhausted through chamber isolation valve 211 and throttle valve 213 to a vacuum pump (not shown). Chamber isolation valve 211 is in the open position, and cleaning isolation valve 217 is in the closed position.

Either before the chamber cleaning process is begun or after the chamber cleaning process is completed, the throttle valve cleaning process of the present invention may be commenced. Chamber isolation valve 211 is closed, and cleaning isolation valve 217 is opened. Before cleaning gases are introduced through cleaning isolation valve 217, purge gases 221 may be flowed through cleaning isolation valve 217, into the exhaust pipe upstream of throttle valve 213, and through throttle valve 213. Purge gases may be inert or “house” gases, such as oxygen (O₂) or nitrogen (N₂) or a mixture of these gases. Purge gases may be flowed at a rate of as much as about 5 standard liters per minute (slm), for as long as about 1 minute.

Cleaning gases 221 are then flowed through cleaning isolation valve 217, into the exhaust pipe upstream of throttle valve 213, and through throttle valve 213. The same cleaning gases used to clean the chamber may be used to clean the throttle valve, or different cleaning gases may be used. For example, when cleaning a throttle valve following a silicon oxide film deposition, nitrogen trifluoride (NF₃), hexafluoroethane (C₂F₆) and oxygen (O₂) may be used. Alternatively, fluorine (F₂) may be used, at a flowrate of about 1 slm for about 20 seconds, depending on the deposited film thickness.

The pressure in the piping between chamber isolation valve 211 and throttle valve 213 should be maintained in the range of about 20 mtorr to about 10 torr. This may be accomplished by reducing the flow of gases 221, and/or by cycling throttle valve 213 between the open and closed positions via a servo-motor (not shown) controlled by a closed-loop control system based on feed-back signals from a pressure manometer (not shown) installed between chamber isolation valve 211 and throttle valve 213. The pressure is preferably measured and stabilized using purge gases, prior to introducing cleaning gases.

The piping between chamber isolation valve 211 and throttle valve 213 need not be heated or cooled during the cleaning method of this invention. However, heating of the piping between chamber isolation valve 211 and throttle valve 213 may enhance the effectiveness of the cleaning gases.

While cleaning gases 221 are being introduced through cleaning isolation valve 217, a plasma may be ignited in the cleaning gas by applying RF power 222, thereby causing the gas to react with the deposited material and etch the material away. The plasma may be generated using any conventional means. For example, a remote RF source may be used, which would require much less power than the chamber RF source. For example, a remote RF source having a power as low as about 5 watts, up to about 1500 watts, may be used for the throttle valve cleaning process. Preferably, an inductive plasma system may be employed to generate plasma for the throttle valve cleaning process. In FIG. 2, RF power is shown being applied in the exhaust flow passage downstream of chamber isolation valve 211 and upstream of throttle valve 213. However, RF power may also be applied in the cleaning gas passage downstream of cleaning isolation valve 217, or even upstream of cleaning isolation valve 217, so long as the distance to be traveled through cleaning isolation valve 217 and to throttle valve 213 is not excessive.

Some types of throttle valves may need to be actuated or rotated while the reactive plasma is being generated. For example, certain vales, such as the MKS throttle valve or the Applied Materials (AMAT) sigma throttle valve, should be repositioned during generation of the reactive plasma in order to effectively clean all surfaces of the valve. Other types of valves, such as a C-plug valve or a dual spring valve, need not be actuated during reactive plasma generation.

After the throttle valve cleaning process is complete, the remaining cleaning gases and any cleaning byproducts are pumped out of the piping and the throttle valve. Optionally, an inert gas may be used to purge the remaining cleaning gases and cleaning byproducts.

While the present invention has been particularly described in conjunction with a preferred embodiment and other alternative embodiments, it is evident that numerous alternatives, modifications and variations will be apparent to those skilled in the art in light of the foregoing description. It is therefore intended that the appended claims embrace all such alternatives, modifications and variations as falling within the true scope and spirit of the present invention.

I claim:

1. An exhaust flow control apparatus attached to a CVD chamber, for controlling an exhaust flow passage and for regulating gas pressure in said CVD chamber, comprising:
an isolation valve in fluid communication with said CVD chamber;
a throttle valve mounted downstream from and in fluid communication with said isolation valve;
means for introducing a cleaning gas into said exhaust flow passage downstream of said isolation valve and upstream of said throttle valve; and
a vacuum pump mounted downstream from and in fluid communication with said throttle valve.

2. The apparatus of claim 1, wherein said means for introducing a cleaning gas comprises a second isolation valve in fluid communication with a cleaning gas source.

3. The apparatus of claim 1, further comprising means for applying RF power in said exhaust flow passage downstream of said isolation valve and upstream of said throttle valve, for generating a reactive plasma of said cleaning gas.

4. The apparatus of claim 3, wherein said means for applying RF power comprises an inductive plasma system.

5. The apparatus of claim 1, further comprising means for controlling said throttle valve.

6. The apparatus of claim 5, wherein said means for controlling said throttle valve comprises a servo-motor.

7. An exhaust flow control apparatus attached to a CVD chamber, for controlling an exhaust flow passage and a cleaning gas flow passage, and for regulating gas pressure in said CVD chamber, comprising:
a first isolation valve in fluid communication with said CVD chamber;
a second isolation valve in fluid communication with a cleaning gas source;
a throttle valve mounted downstream from and in fluid communication with said first isolation valve and said second isolation valve; and
a vacuum pump mounted downstream from and in fluid communication with said throttle valve.

8. The apparatus of claim 7, further comprising an RF power source for generating a reactive plasma of said cleaning gas in said exhaust flow passage downstream of said isolation valve and upstream of said throttle valve.

9. The apparatus of claim 8, wherein said RF power source comprises an inductive plasma system.

10. The apparatus of claim 7, further comprising a servo-motor for controlling said throttle valve.

11. A method for cleaning a throttle valve attached to a CVD chamber, comprising the steps of:
isolating said throttle valve from said CVD chamber;
flowing at least one cleaning gas into said throttle valve at a pressure and for a length of time such that unwanted film deposits are removed from said throttle valve.

12. The method of claim 11, further comprising, prior to the step of flowing said cleaning gas into said throttle valve, the step of generating a reactive plasma of said cleaning gas.

13. The method of claim 12, wherein said reactive plasma of said cleaning gas is generated by an inductive plasma system.

14. The method of claim 12, wherein said reactive plasma of said cleaning gas is generated by applying RF power of about 5 watts to about 1500 watts.

15. The method of claim 11, further comprising, prior to the step of flowing said cleaning gas into said throttle valve, flowing a purge gas into said throttle valve.

16. The method of claim 15, wherein said purge gas is flowed into said throttle valve at a rate less than about 5 slm and for a time less than about 1 minute.

17. The method of claim 11, wherein said cleaning gas is selected from the group consisting of nitrogen trifluoride, hexafluoroethane and oxygen.

18. The method of claim 11, wherein said cleaning gas comprises fluorine.

19. The method of claim 11, wherein said pressure is about 20 mtorr to about 10 torr.
